(19) United States
(12) Patent Application Publication
(10) Pub. No.: US 2009/0315055 A1
(43) Pub. Date: Dec. 24, 2009

(54) PHOTOELECTROCHEMICAL ROUGHENING OF P-SIDE-UP GaN-BASED LIGHT EMITTING DIODES

(75) Inventors: Adele Tamboli, Goleta, CA (US); Evelyn Lynn Hu, Goleta, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/464,711

(22) Filed: May 12, 2009

Related U.S. Application Data
(60) Provisional application No. 61/052,417, filed on May 12, 2008.

(51) Int. Cl. H01L 33/00

(52) U.S. Cl. 257/98; 438/29; 257/103; 257/E33.074; 257/E33.025

(57) ABSTRACT

A method for photoelectrochemical (PEC) etching of a p-type gallium nitride (GaN) layer of a heterostructure, comprising using an internal bias in a semiconductor structure to prevent electrons from reaching a surface of the p-type layer, and to promote holes reaching the surface of the p-type layer, wherein the semiconductor structure includes the p-type layer, an active layer for absorbing PEC illumination, and an n-type layer.

### CROSS REFERENCE TO RELATED APPLICATIONS

This application claims the benefit under 35 U.S.C. Section 119(e) of co-pending and commonly-assigned U.S. Provisional Patent Application Ser. No. 61/052,417, filed on May 12, 2008, by Adele Tamboli, Evelyn L. Hu, Steven P. DenBaars and Shuji Nakamura, entitled “PHOTOELECTROCHEMICAL ROUGHENING OF Ga-FACE, P-SIDE-UP GaN-BASED LIGHT EMITTING DIODES,” attorneys' docket number 30794.271-US-P1 (2008-535-1);

which application is incorporated by reference herein.

This application is related to the following co-pending and commonly-assigned U.S. patent applications:

U.S. Utility application Ser. No. xx/xxx,xxx, filed on same date herewith, by Adele Tamboli, Evelyn L. Hu, Matthew C. Schmidt, Shuji Nakamura, and Steven P. DenBaars, entitled “PHOTOELECTROCHEMICAL ETCHING OF P-TYPE SEMICONDUCTOR HETEROSTRUCTURES,” attorney's docket number 30794.272-US-U1 (2008-533), which application claims the benefit under 35 U.S.C. Section 119(e) of U.S. Provisional Application Ser. No. 61/052,421, filed on May 12, 2008, by Adele Tamboli, Evelyn L. Hu, Matthew C. Schmidt, Shuji Nakamura, and Steven P. DenBaars entitled “PHOTOELECTROCHEMICAL ETCHING OF P-TYPE SEMICONDUCTOR HETEROSTRUCTURES,” attorney's docket number 30794.272-US-P1 (2008-533); and

U.S. Utility application Ser. No. 10/581,940, filed on Jun. 7, 2006, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C Section 365(c) of PCT Application Serial No. US2003/03921 1, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Provisional Application Ser. No. 61/104,015, filed on Oct. 9, 2008, by Adele Tamboli, Evelyn L. Hu, and James S. Speck, entitled “PHOTOELECTROCHEMICAL ETCHING FOR CHIP SHAPING OF LIGHT EMITTING DIODES,” attorney's docket number 30794.289-US-P1 (2009-157); and

U.S. Provisional Application Ser. No. 61/148,679, filed on Jan. 30, 2009, by Adele Tamboli, Evelyn L. Hu, Arpan Chakraborty, and Steven P. DenBaars, entitled “PHOTOELECTROCHEMICAL ETCHING FOR LASER FACETS,” attorney's docket number 30794.301-US-P1 (2009-360);

which applications are incorporated by reference herein.

### BACKGROUND OF THE INVENTION

1. Field of the Invention

This invention relates to a process to roughen the p-type surface of GaN-based light emitting diodes (LEDs) using photoelectrochemical (PEC) etching.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Roughened LEDs have been proposed and developed in the past for other material systems, including GaP [1]. PEC etching has been used previously to roughen GaN-based LEDs, but the process was only applicable to N-face, n-type LEDs. Because of issues related to the growth and doping of GaN heterostructures, growth typically proceeds with any p-type layers grown last. Thus, PEC roughening of LEDs has always previously required the removal of the sapphire substrate and bonding the LED to a submount so that the n-type, N-face side is exposed.

Despite the fact that substrate removal and flip-chip bonding is an expensive and difficult process, PEC roughening in this manner has already been embraced by LED manufacturers.

T. Fujii et al. first used PEC etching in conjunction with a laser liftoff process to fabricate (n-type) roughened GaN LEDs, which showed an increase in light extraction by a factor of 2-3 times, as is disclosed in U.S. Patent Publication No. 2007/0121690 (which is cited above as U.S. Utility application Ser. No. 10/581,940, filed on Jun. 7, 2006, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C Section 365(c) of PCT Application Serial No. US2003/03921 1, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063)), which applications and publication are incorporated by reference herein.

There has also been a report of using a KOH/ethylene glycol wet etch to roughen the surface of p-GaN purely chemically [2]. However, elevated temperatures were necessary for the etch to proceed, and etching initiated at defects, providing fairly dispersed etch pits which led to a relatively smooth surface overall. It is also possible to use dry etching to achieve roughened LEDs, but dry etching introduces ion damage into the material, which is detrimental to optical and electronic properties.

Thus, there is a need in the art for improved processes for roughening LEDs. The present invention satisfies this need.

### SUMMARY OF THE INVENTION

To overcome the limitations in the prior art described above, and to overcome other limitations that will become apparent upon reading and understanding the present specification, the present invention describes a process to roughen the p-type surface of GaN-based LEDs using PEC etching.

The present invention discloses an LED, comprising a roughened surface of a p-type layer, wherein the roughened surface scatters light incident on the roughened surface into an external medium, wherein the light is incident from a light-emitting active layer of the LED. For example, the LED may comprise a p-type III-nitride layer having a surface which is roughened for extracting light emitted by the LED; an n-type III-nitride layer; and an active layer for emitting the light, between the p-type III-nitride layer and the n-type III-nitride layers.

The p-type III-nitride layer, n-type III-nitride layer and active layer may have no ion damage introduced by the roughening process. Furthermore, material qualities of the p-type III-nitride layer, n-type III-nitride layer and active layer may be such that a current-voltage (I-V) measurement of the LED having the surface which is roughened is not substantially different, or degraded, as compared to an I-V measurement of the LED prior to the surface being roughened.

The surface may be roughened to create features or structures so dimensioned to extract the light out of the p-type layer and the LED, for example, to extract more of the light out of, or transmit more of the light through, the surface as compared to extraction out of, or transmission through, a surface of the p-type layer prior to the roughening or a surface without the features or structures. The features or structures may be so dimensioned to scatter, diffract, refract or direct the light out of the p-type layer and the LED. The features or structures may be so dimensioned as to cause at least 20% more light output power to be transmitted through the surface and exit the LED, as compared to a light output power that is transmitted through the surface prior to the roughening and without the structures, and/or as compared to a light output power that is transmitted through a planar, flat or smooth surface of the p-type layer that has a surface roughness of 1 nm or less. Typical root mean square (rms) roughnesses are 1 nanometer (nm) for as-grown material and 20-30 nm for roughened material of the present invention.

More specifically, the features or structures may have a side, dimension, width, height and separation so dimensioned as to scatter or diffract the light out of the p-type layer and the LED. Furthermore, the side, dimension, width, height and separation may be least as long as a wavelength of the light in the p-type layer, in order to enhance scattering, diffraction, or transmission of the light out of the p-type layer and the LED. For example, the side, the dimension, the width, the height, and the separation may be at least 0.3 micrometers (μm), at most 2 μm, or at most 10 μm.

The surface of the p-type layer may be shaped so that light from the active layer impinges on the surface within a critical angle for refraction out of the p-type layer and into an external medium. For example, the surface may comprise one or more inclined surfaces so dimensioned (e.g., inclined at the critical angle) that the light impinges on the inclined surfaces within the critical angle, thereby substantially preventing total internal reflection of the light at the inclined surfaces. Without any light extraction techniques, only 4-6% of the emitted light can escape from a GaN LED. With surface texturing of the present invention, more than 4-6% of the light hits the surface within the critical angle, leading to increased light extraction.

In another example, the surface comprises a surface roughness of 20 nm or greater, or 25 nm or greater. The roughening may be formed on an N-face, Ga-face, nonpolar surface, or semipolar surface of the p-type layer, for example.

The present invention further discloses a method for fabricating a III-nitride based LED, comprising roughening a p-type surface of the III-nitride-based light emitting LED, wherein the roughening comprises PEC etching the p-type surface and the roughening is suitable to extract light from the LED.

### BRIEF DESCRIPTION OF THE DRAWINGS

Referring now to the drawings in which like reference numbers represent corresponding parts throughout:

FIG. 1 is a PEC etching schematic.

FIG. 2(a) is a cross-sectional schematic of a p-i-n heterostructure, and FIG. 2(b) is a schematic energy band diagram at the surface of the p-type layer of the LED and as a function of position through the layers of the structure in FIG. 2(a), showing carrier pathways in the LED/electrolyte system.

FIG. 3(a) is a scanning electron micrograph (SEM) image of a roughened p-type, Ga-face surface of an LED (scale 2 μm), taken from a 45° angle, showing a lateral variation in roughness.

FIG. 3(b) is an image of a roughened semipolar (11-22) surface, wherein the scale is 20 μm.

FIGS. 4(a)-(e) is a schematic illustrating a process flow for making a roughened GaN/InGaN LED.

FIG. 5(a) is a cross-sectional schematic showing surface roughening of a p-GaN up LED.

FIG. 5(b) is a top view optical image of an LED showing a non-roughened p-type surface, wherein the surface roughness is 1 nm.

FIG. 5(c) is a top view optical image of a portion of the surface in FIG. 5(b), wherein the scale in the plane of the image is 2.5 μm and the gray scale provides a height profile or surface roughness and the surface roughness is ˜1 nm.

FIG. 5(d) is a top view optical image of an LED having the structure of FIG. 5(a), showing the roughened p-type surface, a lateral variation in roughness, and a surface roughness of ˜25 nm.

FIG. 5(e) is a top view optical image of a portion of the surface in FIG. 5(d), wherein the scale in the plane of the image is 2.5 (μm), the gray scale provides a height profile or surface roughness (same scale as in FIG. 5(c)), and the surface roughness is ˜25 nm.

FIG. 5(f) is a top view SEM image of a portion of the surface in FIG. 5(d) and shows the same surface as in FIG. 3, wherein the scale is 2 μm.

FIG. 6(a) plots voltage (V) vs. current (mA) (current-voltage (I-V) characteristics or measurement) and output power (arbitrary units, a.u.) vs. current, for 7 smooth LEDs and 7 rough LEDs adjacent on the same sample, showing no degradation of I-V characteristics between the smooth LEDs and the rough LEDs, and also showing not much variation in the electroluminescence properties between the rough LEDs and the smooth LEDs, so that the average light output power of the 7 smooth LEDs and the average light output power of the 7 rough LEDs is also plotted as a function of the drive current.

FIG. 6(b) plots enhancement factor as a function of drive current (mA) for the rough LEDs of FIG. 6(a) as compared to the smooth LEDs of FIG. 6(a), showing 20% enhancement of light extraction for the rough LEDs compared to the nearby smooth LEDs, wherein the average enhancement for all the rough LEDs is also shown, and the enhancement factor is light output power for the rough LEDs divided by light output power for the smooth LEDs.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

While the performance of most III-nitride LEDs is limited by total internal reflection of the emitted light in the semiconductor, roughened LEDs increase light extraction by scattering the light that is incident on the roughened surface into the air. Roughening of LEDs to increase extraction is not a new technique, but PEC etching is a fast, inexpensive way to roughen the surface without introducing ion damage.

PEC etching has thus far been used to roughen only the N-face, n-type side of III-N LEDs. Because of issues related to the growth and doping of GaN heterostructures, growth typically proceeds with the Ga face up, and any p-type layers are usually grown last. Thus, PEC roughening of LEDs has always previously required the removal of the sapphire substrate and bonding the LED to a submount so that the n-type, N-face side is exposed.

In contrast, the present invention has been able to achieve PEC roughening of the Ga-face, p-type side of the LED, which is naturally the top surface during growth.

Technical Description

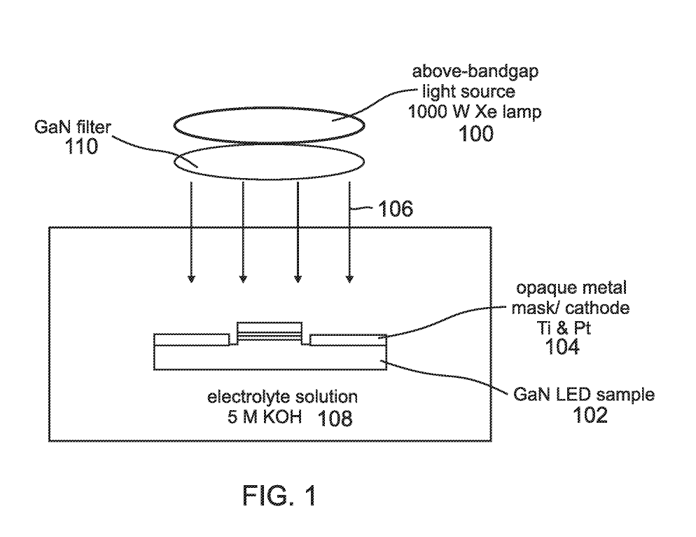

PEC etching consists of a light source (e.g., above-bandgap 1000 Watt Xe lamp 100) and an electrochemical cell, where the semiconductor (of the, e.g., GaN LED sample 102) acts as the anode of the system and has metal 104 (usually platinum (Pt) or Ti/Pt) patterned directly on it to act as the cathode (FIG. 1). Light 106 generates electron-hole pairs in the semiconductor, and electrons are extracted through the cathode 104, while holes participate in oxidation reactions at the semiconductor surface, causing the semiconductor surface to be dissolved in an electrolyte 108. Because of the surface band bending at the semiconductor/electrolyte interface, holes are typically confined at the surface in n-type materials only, while electrons are confined at the surface in p-type materials. For this reason, PEC etching of p-type semiconductors has been difficult to achieve. FIG. 1 also shows that the light 106 may be filtered, e.g., using a GaN filter 110. The p-GaN of the LED 102 is the anode for the PEC etching.

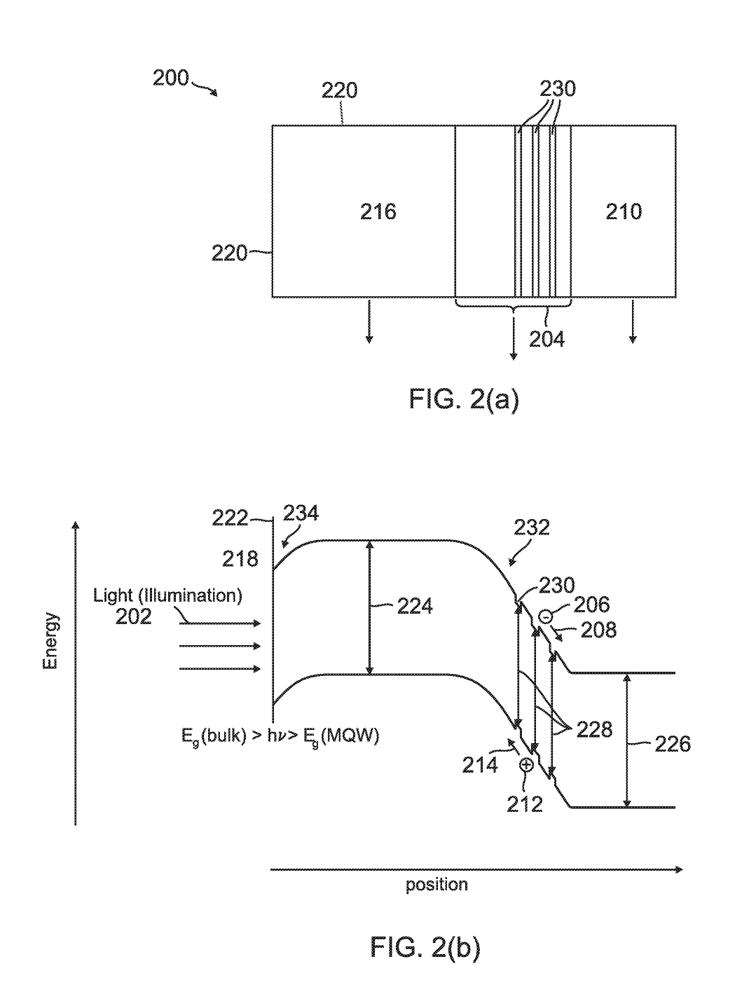

For example, using a standard LED structure 200, a light source can be chosen that emits light 202 that is absorbed only or mainly in the quantum well region 204, and the doping of the structure 200 spatially separates the photogenerated carriers such that electrons 206 are pulled 208 into the n-type layer 210, where they can escape through the cathode, and holes 212 are pulled 214 into the p-type cap layer 216 (FIG. 2(a) and FIG. 2(b)). By using a strongly basic solution such as KOH as an electrolyte 218, the photogenerated holes 212 can make it to the surface 220 (e.g., any interface 222 of the p-type layer 216 with the electrolyte 218) to participate in etching reactions. In this way, the p-type surface 220 of a heterostructure 200 can be etched without the need for dry etching. The bandgap E_{g}(bulk) 224, 226 of the bulk 216, 210, is greater than the bandgap E_{g}(MQW) 228 of the quantum wells 230 (e.g., multi quantum wells, MQWs) so that the light 202 of photon energy hv (where h is Planck's constant and v is the frequency of the light 202) is only absorbed in the quantum wells 230 of the quantum well region 204.

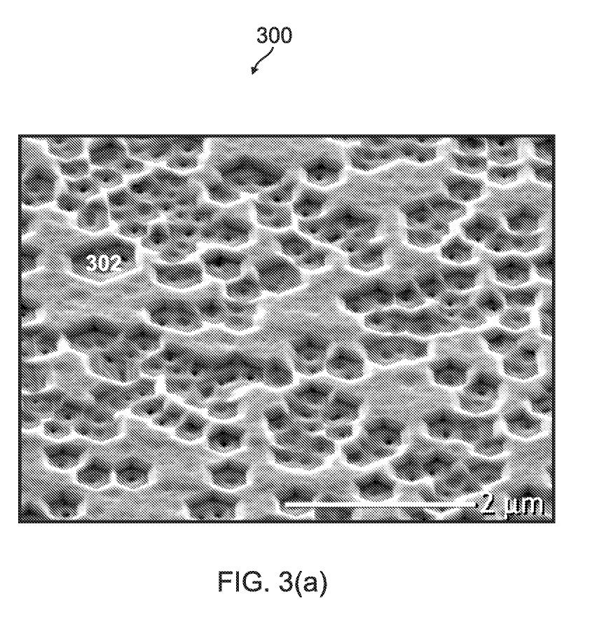

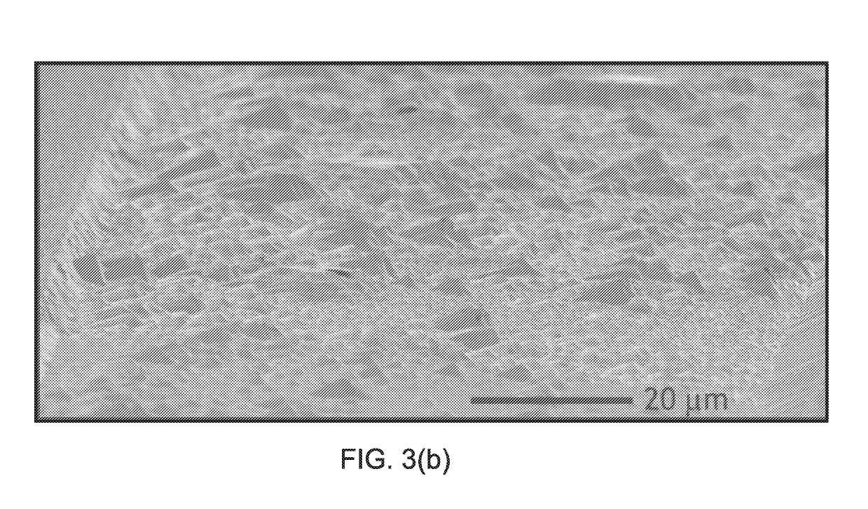

Electron-hole pairs are generated in the low-bandgap layer 230, and they are separated by the built-in fields of the p-n junction 200 (the built-in-field is proportional to the slope 232 of conduction band E_{c} and valence band Eᵥ between the p-type region 216 and n-type region 210). By using a strongly basic solution 218, the surface band-bending 234 can be minimized such that many of the photogenerated holes 212 make it to the surface 220 to participate in etching reactions. A careful balance of etch conditions can produce a roughened rather than smoothly etched p-GaN surface 220, and this allows the present invention to form p-side-up, Ga-face roughened LEDs (FIG. 3(a)). As shown in FIG. 3(a), the resulting p-GaN surface 300 has features such as pits 302. In FIG. 3(a), the surface comprises etched pits and unetched regions, or smooth regions between pits; the sidewalls are somewhat inclined and not smooth on the bottom. However, there can be a lot of variation depending on etch conditions and starting material, including various positions on the same wafer. FIG. 3(b) is an image of a roughened semipolar (11-22) surface that illustrates how much variation there can be.

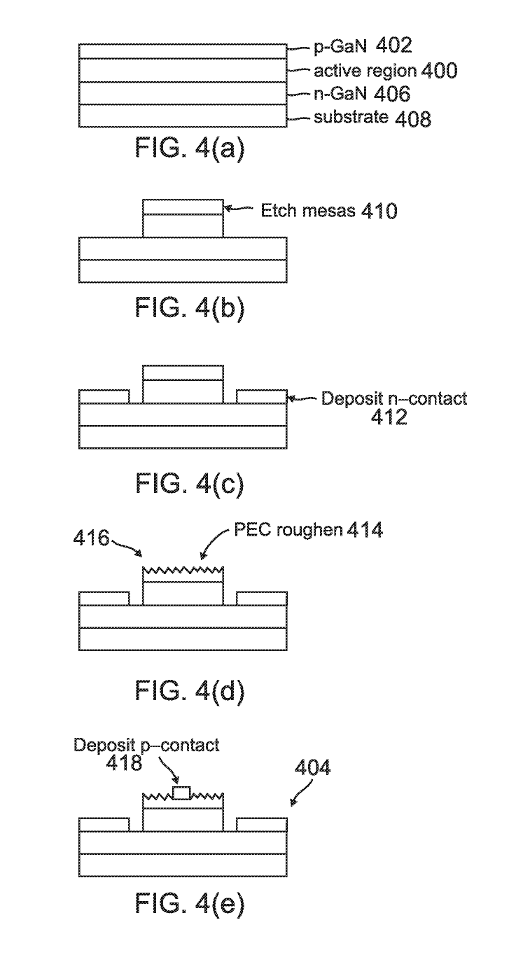

In the present invention's process for making roughened LEDs, the quantum wells as a low-bandgap absorption layer are utilized to separate the generation of electron-hole pairs from the area that is to be etched, allowing holes to travel to the surface while electrons are driven by the internal field out through the cathode. This process introduced only one extra step into the fabrication process for GaN-based LEDs. An example of the process is given below and shown schematically in FIGS. 4(a)-(e). The use of quantum wells (in the active region 400) does not require a change to the material growth and standard LED material may be used for the process, as shown in FIG. 4(a). The only requirement is that the quantum wells be lower in bandgap than the p-type layer's 402 bandgap, which is typically the case.

Fabrication Method

Further information on the PEC etching method can be found in U.S. Utility application Ser. No. xx/xxx,xxx, filed on same date herewith, by Adele Tamboli, Evelyn L. Hu, Matthew C. Schmidt, Shuji Nakamura, and Steven P. DenBaars, entitled “PHOTOELECTROCHEMICAL ETCHING OF P-TYPE SEMICONDUCTOR HETEROSTRUCTURES,” attorney's docket number 30794.272-US-U1 (2008-553), which application claims the benefit under 35 U.S.C Section 119(e) of U.S. Provisional Application Ser. No. 61/052,421, filed on May 12, 2008, by Adele Tamboli, Evelyn L. Hu, Matthew C. Schmidt, Shuji Nakamura, and Steven P. DenBaars entitled “PHOTOELECTROCHEMICAL ETCHING OF P-TYPE SEMICONDUCTOR HETEROSTRUCTURES,” attorney's docket number 30794.272-US-P1 (2008-533), which applications are cited above and incorporated by reference herein.

FIG. 4(a)-(e) illustrate a method for fabricating a III-nitride (e.g., GaN) based LED 404. The method comprises one or more of the following steps:

1. Using an LED structure 404 with activated p-GaN 402. This may comprise depositing a III-nitride n-type layer 406 (e.g., n-type GaN or n-GaN) on a substrate 408 (e.g., sapphire substrate), depositing a III-nitride active region 400 (e.g., InGaN quantum well active layer) on the n-type GaN layer 406 (e.g. n-GaN), and depositing the p-type III-nitride layer (e.g., p-type GaN layer or p-GaN) 402 on the InGaN active layer 400. The following steps are then performed in a typical fabrication process, as shown in FIG. 4(b)-(e):

2. Masking and etching LED mesas 410, as shown in FIG. 4(b), by e.g., etching one or more mesas in the p-type GaN layer 402 and the InGaN active layer 400.

3. Depositing a cathode 412 everywhere in the field around the LED mesas 410, as shown in FIG. 4(c), e.g., by depositing one or more n-contacts 412 on the n-type GaN layer 406. Surface area is important for the etching reaction to proceed rapidly. Pt can be used to enhance the etch rate, but is not necessary. This metal 412 can be used as the n-contact.

4. Performing a PEC etch on the structure formed in steps 1-3. Specifically, performing PEC roughening 414 of the p-GaN's 402 surface 416 (through which light is extracted), as shown in FIG. 4(d). For example, PEC illumination may be predominantly absorbed in the InGaN active layer 400, so that the InGaN layer active layer 400 photogenerates electrons and holes. This step may use an internal bias in the semiconductor structure 404 to prevent electrons from reaching the surface 416 of the p-type GaN layer 402 and to promote holes reaching the surface 416 of the p-type GaN layer 402. For example, doping of the structure 404 may spatially separate the electrons and holes photogenerated by the absorption in the InGaN active layer 400, such that the electrons are pulled into the n-type GaN layer 406, wherein the electrons escape through the n-contacts 412 acting as cathodes, and holes are pulled into the p-type GaN layer 402, wherein the holes participate in etching reactions, with a basic or acidic solution, at the surface 416 of the p-type GaN layer 402, and the etching reactions create roughening 414 of the surface 416 of the p-type GaN layer 402 suitable for extracting light from the LED 404.

The ideal conditions are use of a 5 M KOH electrolyte solution and a 1000 W Xe lamp filtered through GaN, so that electron-hole pairs are only generated in InGaN of the active region 400, and the lamp focussed for intense illumination.

A factor that may determine whether a smooth or rough surface is achieved is the material used. Typically, the defects and crystallographic etching from using c-plane or some orientations of semipolar GaN lead to rough surfaces, while nonpolar or low defect density material typically yields smooth surfaces. There is some tunability based on which electrolyte is chosen, its concentration, the illumination intensity, and whether the solution is stirred during etching. For rough surfaces, concentrated KOH as an electrolyte with less intense illumination and no stirring may be used. Also, stopping the etch before reaching any etch-stop layers will ensure that the surface does not smooth out.

5. Depositing a p-contact 418 on the roughening 414, as shown in FIG. 4(e). The end result is an LED 404. The present invention is not limited to LEDs, but the semiconductor structure 404 typically includes the p-type layer 402, an active layer 400 for absorbing PEC illumination (and emitting light in the fabricated light emitting device 404), and an n-type layer 406.

Therefore, FIGS. 4(a)-(e) illustrate a method for fabricating a III-nitride based LED 404, comprising roughening 414 a p-type surface 416 of the LED 404, wherein the roughening 414 comprises PEC etching the p-type surface 416 and the roughening 414 is suitable to extract light from the LED 404. The method may also work in other material systems, as well as for some other orientations of GaN besides c-plane.

LED structure

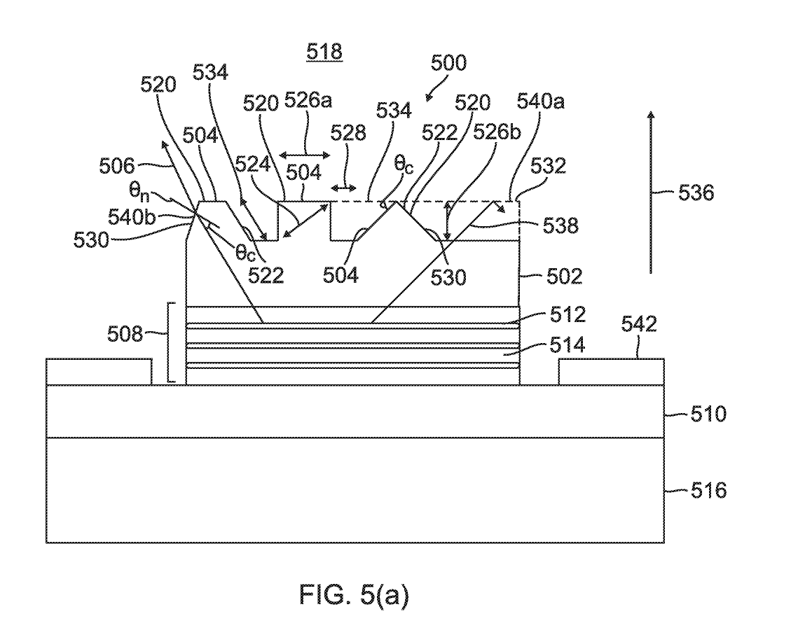

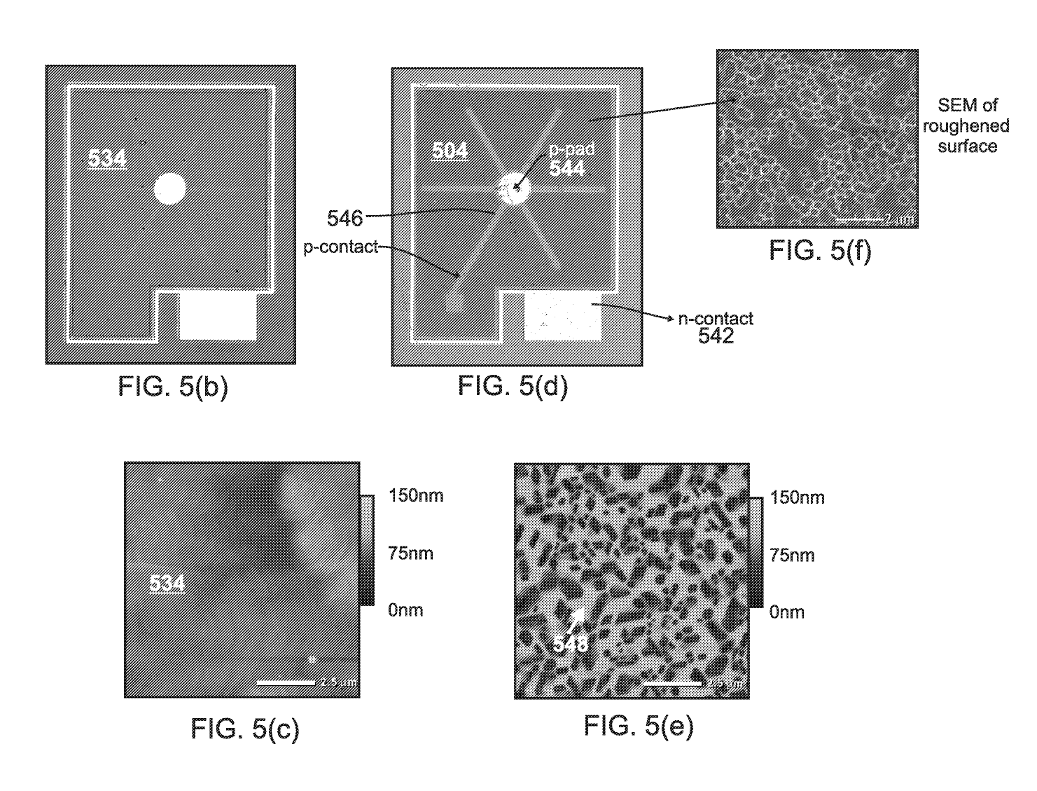

FIG. 5(a) is a schematic cross-section of an LED structure 500 of the present invention, comprising (a) a p-type III-nitride layer 502 (e.g., p-type GaN) having a surface 504 which is roughened for extracting light 506 emitted by the active layer or region 508 of the LED 500; and (b) an n-type III-nitride layer 510 (e.g., n-type GaN). The light emitting active layer 508 (e.g., InGaN quantum wells 512, for emitting light 506, between GaN barriers 514), is between the p-type III-nitride layer 502 and the n-type III-nitride layers 510. The p-type III-nitride layer 502, n-type III-nitride layer 510, and active layer 508 may have no ion damage introduced by the roughening process, or reduced ion damage as compared to a dry etched p-type layer 502. The n-GaN 510 is typically on a substrate 516, such as sapphire.

FIG. 5(a) also illustrates an LED 500 (e.g., III-nitride based) that enhances light extraction, comprising a surface 504 of a p-type layer 502 (e.g., p-type III-nitride) that is roughened, wherein the roughened surface 504 scatters, or increases scattering of, light 506 incident on the roughened surface 504 into the external medium 518 (external to the LED 500, such as, but not limited to, air or epoxy), wherein the light 506 is incident from a light-emitting active layer 508 of the LED 500.

The surface 504 of the p-type layer 502 may be roughened or structured to create structures or features 520 so dimensioned (e.g., with dimensions similar to the wavelength of emitted light) to extract or enhance light 506 extraction out of (or transmission through) a surface of a semiconductor in an LED. For example, the extraction may include, but is not limited to, light scattering, diffraction, refraction, or direction out of the p-type layer and the LED, and the features or structures 520 are so dimensioned to extract (e.g., scatter, diffract, direct, or refract) the light 506 out of the surface 504, the p-type layer 502, and the LED 500, into the external medium 518. The features or structures 520 should be so dimensioned to extract (transmit) more of the light 506 out of (through) the surface 504 as compared to extraction out of, or transmission through, a surface of the p-type layer 502 prior to the roughening of the surface of the p-type layer 502, (or as compared to a non-roughened/non-structured surface without the features or structures 520).

Without being bound by a specific scientific principle, theory or example, various examples, principles, and theories are provided below.

In order to enhance light extraction, the surface 504 may have a roughness that varies optimally at approximately the scale of the wavelength of light in the structure 500. For example, the width or lateral variation of the roughness in the present invention might be comparable to the wavelength of light. A surface with features (such as pits) every 10 μm might improve light extraction as compared to an absolutely smooth surface, but the improvement might not be significant or much better. Similarly, a surface roughness having a periodicity of approximately a few angstroms might have a smaller effect on the light extraction than features/surface roughness that varies on the scale of a wavelength of the light.

In another example, the features 520 typically have one or more sides 522, edges, or dimensions 524 (including, but not limited to, a width 526a and/or height 526b) and/or separations 528 so dimensioned (e.g., have a length at least as long as the wavelength of the light 506 in the p-type layer 502) so that the features or structures 520 can influence the light's 506 propagation direction, e.g., scatter, diffract, refract, or otherwise direct the light 506 out from the p-type layer 502 and the LED 500, into the external medium 518.

For example, the lengths, dimensions 524, or separations 528 may be, but are not limited to, at least 0.3 μm, at least 0.3 μm and at most 2 μm, at least 0.3 μm and at most 10 μm, or between 1 μm and 2 μm. The features/structures 520 may be adjacent one another, so that the separation 528 is substantially smaller than the wavelength of the light 506. As noted above, the dimensions 524 and separation 528 selected may depend on the wavelength of the light 506 emitted.

Alternatively, or in addition, the surface 504 may be shaped so that most light 506 from the active layer 508 impinges on the surface 504 within a critical angle θ_{c} for refraction out of the p-type layer 502 and into the external medium 518. For example, the surface 504 may shaped with, or comprise, slopes or inclined surfaces 530 so that most light 506 from the active layer 508 impinges on the surface 504 within a critical angle θ_{c} (with respect to the surface normal θₙ) for refraction out of the p-type layer 502 and surface 504. The critical angle may be defined as θ_{c}=arcsin(n₂/n₁), where n₂ is the refractive index of the external medium 518 contacting the surface 504 of the LED 500 (material 518 into which the light 506 from the LED 500 is extracted), and n₁ is the refractive index of the p-type III-nitride layer 502. The dotted line 532 indicates a portion of the p-type 502 surface prior to roughening, and typically, the slopes or inclined surfaces 530 are at the angle θ_{c} with respect to the non-roughened, planar, and/or smooth surface 534 (prior to roughening of the present invention). The surface 534 may be an epitaxially grown surface 534, perpendicular to the growth direction 536 (e.g., c-axis, (0001), (000-1), nonpolar or semipolar directions 536) of the LED 500, and may be an N-face, Ga-face, semipolar plane, nonpolar plane, for example. The surface 534 may be a miscut or misoriented surface, for example. The surface 504 may comprise crystallographic facets of the p-type III-nitride 502, for example.

For further illustration of the effect of the critical angle θ_{c}, also shown in FIG. 5(a) is the trajectory of light 538, emitted by the active layer 508 that is totally internally reflected when incident on a non-roughened surface 534 of the p-type layer 502 (or incident on non-roughened interface 540a between the p-type layer 502 and external medium 518). The present invention illustrates that the surface 504 may be so shaped to substantially prevent total internal reflection of the light 538. More specifically, the inclined surfaces 530 may be so dimensioned that the light 506 impinges on the inclined surfaces 530 within the critical angle θ_{c}, thereby substantially preventing total internal reflection of the light 538 at the inclined surfaces 530 and/or more than 4-6% of the light 506 from the active layer 508 is extracted.

It may also be considered that the present invention roughens or structures the interface 540a, thereby creating roughened interface 540b, to scatter, refract, or transmit light 506 incident on the interface 540b into the external medium 518. For example, the present invention may roughen the surface 534 or interface 540a, for reducing or extracting the totally internally reflected light 538 emitted by the LED 500 (e.g., by impinging the light 506 on the interface 540b within the critical angle θ_{c}).

Also shown in FIG. 5(a) is the cathode or n-contact 542.

FIG. 5(b) is a top view optical image of an LED having the structure of FIG. 5(a) but without roughening of the surface 534 of the p-type III-nitride layer 502 (e.g., the surface 534 is the smooth “as grown” surface, which is smooth enough/so dimensioned for total internal reflection of light 538 to occur within the p-type material 502 at the interface 540a between the p-type layer 502 and external medium 518). FIG. 5(c) is an optical image of a portion of the p-type surface 504 in FIG. 5(b), showing a planar or smooth surface 534 with a surface roughness less than 1 nm over an area of 2.5 μm×2.5 μm. In order to extract light, the surface 504 should be rougher than the surface 534, and therefore the present invention may roughen or structure the surface 534 to create surface 504.

FIG. 5(d) is a top view optical image of an LED of the present invention having the structure of FIG. 5(a), showing the p-type surface 504 with roughening (surface roughness ˜25 nm), and further comprising a p-type pad 544 on a p-contact 546, wherein the p-contact 546 makes ohmic contact to the p-type surface 504, and the n-contact 542 makes ohmic contact to the n-type layer 510. FIG. 5(e) is an optical image of a portion of the roughened surface 504 in FIG. 5(d), showing a pitted surface comprised of pits 548 at least ˜25 nm deep, less than 1 μm wide, and separated by less than 2.5 μm (and surface roughness ˜25 nm). FIG. 5(f) is an SEM image of a portion of the roughened surface 504 in FIG. 5(d).

In FIG. 5(e) and FIG. 3(a) the pits 548 are hexagonal in shape. However, this shape will vary for different crystal faces, and does not affect the ability to scatter light.

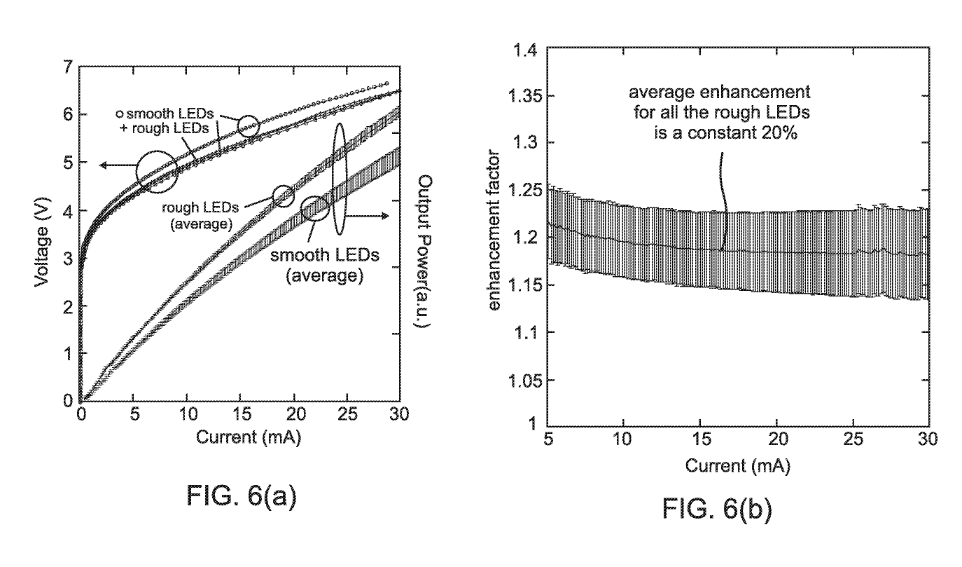

FIG. 6(a) illustrates that material qualities of the p-type III-nitride layer 502, n-type III-nitride layer 510, and active layer 508 are such that an I-V measurement of the LED having the surface 504 which is roughened (e.g., the LED of FIG. 5(d)) is not substantially different, or degraded, as compared to (1) an I-V measurement of the LED having a smooth, planar, flat, or non-roughened surface 534 of the p-type layer 502, and/or (2) an I-V measurement of the LED prior to the surface 534 being roughened (e.g., as compared to the LED of FIG. 5(b)). More specifically, the resistance of the smooth and rough devices is the same to within normal variation in the material (i.e., there is more variation among smooth (or rough) LEDs than between the rough and smooth LEDs. This means the LED 500 (e.g., the LED of FIG. 5(d)), including the p-type layer 502, n-type layer 510, and active layer 508, have substantially similar material quality (e.g., similar defect density, layer thicknesses, and conductivity, etc.) as compared to a smooth LED (e.g., the LED of FIG. 5(b)).

Generally, without texturing of the surface 534, only 4-6% of the light escapes from the LED. The present invention textures the surface 504 so that more than 4-6% of the light escapes. FIGS. 6(a) and 6(b) illustrate the LED 500 of the present invention, wherein the surface 504 is roughened or structured with features 520 or structures that are so dimensioned as to cause at least 20% more light output power to be transmitted through the surface 504 and exit the LED 500, as compared to: (1) a light output power that is transmitted through a smooth or non-roughened surface 534 of a p-type layer 502 without the structures 520, (2) a planar, flat, or smooth surface of the p-type layer that has a surface roughness of 1 nm or less and/or as compared to (3) a light output power that is transmitted through the surface 534 prior to the roughening. For example, the roughened LED of FIG. 5(d) has at least 20% more light output power, due to the roughening, as compared to the light output power of the smooth LED of FIG. 5(b).

Growth of the III-nitride LED 500 typically proceeds with the Ga face of each layer 502, 508, 510 up (i.e. the last grown surface of each layer 502, 508, 510 is a Ga-face), and any p-type layers 502 are usually grown last, so that the surface 534 of the p-type layer 502 that is to be roughened or the structured by the present invention is typically Ga-face. However, the present invention is not limited to particular surfaces 534 or growth directions 536—for example, roughening may be formed on an N-face or Ga-face of the p-type layer 502.

Further information on the present information can be found in [6].

Possible Modifications and Variations

Other electrolytes, including acids, may work, but a strong base will provide a minimal amount of surface band-bending, enhancing the etch rate. Other light sources could also be used as long as they are intense enough and excite carriers mainly in the quantum wells, or in any other layer that is separate from the layer to be roughened. This process could also be applied to other crystalline faces, such as the N-face and various semipolar planes, as long as the p-type layer is on top. In the case of N-face LEDs, cones rather than pits should form, which may be even more efficient for light extraction.

The surface is not limited to a roughened surface; it may be a textured surface, grating structure, or photonic crystal, for example.

Advantages and Improvements

P-side-up, roughened GaN/InGaN LEDs will be significantly brighter than conventional LEDs, while remaining inexpensive to fabricate. The present invention's process significantly improves the performance of III-Nitride based LEDs while introducing few extra processing steps, so it can greatly improve performance with little anticipated increase in costs. PEC roughening of the n-side of LEDs is already being embraced by LED companies, despite the requirement of substrate removal to expose the n-type face. P-side roughening provides similar advantages, but because of the relative ease of fabrication, could have a much greater impact. For example, the present invention does not require removal of the substrate.

### REFERENCES

The following references are incorporated by reference herein.

[1] U.S. Pat. No. 3,739,217, issued Jun. 12, 1973, to Bergh et al., entitled “Surface Roughening of Electroluminescent Diodes.”

[2] Na et al., “Selective Wet etching of p-GaN for Efficient GaN-Based Light Emitting Diodes,” IEEE Photon. Tech. Lett., Vol. 18, No. 14, p. 1512 (2006).

[3] U.S. Pat. No. 5,773,369, issued Jun. 30, 1998, to Hu, Evelyn and Minsky, Milan, entitled “Photoelectrochemical Wet Etching of Group III Nitrides.”

[4] Hwang, J. M. et al., “Efficient wet etching of GaN and p-GaN assisted with chopped UV source,” Superlattices and Microstructures 35, p. 45 (2004).

[5] Fujii et. al. Appl. Phys. Lett. 84 (2004).

[6] Adele C. Tamboli, Kelly C. McGroddy, and Evelyn Hu, “Photoelectrochemical roughening of p-GaN for light extraction from GaN/InGaN light emitting diodes,” physica status solidi, 27 Oct. 2008.

[7] Adele C. Tamboli, Asako Hirai, Shuji Nakamura, Steven P. DenBaars, and Evelyn Hu, “Photoelectrochemical etching of p-type GaN heterostructures,” Applied Physics Letters 94, p. 151113 (2009).

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A light emitting diode (LED), comprising:
(a) a p-type III-nitride layer having a surface which is roughened for extracting light emitted by the LED;
(b) an n-type III-nitride layer; and
(c) an active layer for emitting the light, between the p-type III-nitride layer and the n-type III-nitride layers.

2. The LED of claim 1, wherein the p-type III-nitride layer, n-type III-nitride layer and active layer have no ion damage introduced by a roughening process of the surface.

3. The LED of claim 1, wherein material qualities of the p-type III-nitride layer, n-type III-nitride layer and active layer are such that a current-voltage (I-V) measurement of the LED having the surface which is roughened is not substantially different, or degraded, as compared to an I-V measurement of the LED prior to the surface being roughened.

4. The LED of claim 1, wherein the surface is roughened to create features or structures so dimensioned to extract the light out of the p-type layer and the LED.

5. The LED of claim 4, wherein the surface is roughened to create features or structures so dimensioned to extract more of the light out of, or transmit more of the light through, the surface as compared to extraction out of, or transmission through, a surface of the p-type layer prior to the roughening or a surface without the features or structures.

6. The LED of claim 5, wherein the features or structures are so dimensioned to scatter, diffract, refract or direct the light out of the p-type layer and the LED.

7. The LED of claim 1, wherein the surface is roughened with features or structures that are so dimensioned as to cause at least 20% more light output power to be transmitted through the surface and exit the LED, as compared to a light output power that is transmitted through the surface prior to the roughening and without the structures.

8. The LED of claim 1, wherein the surface is roughened or structured with structures that are so dimensioned as to cause at least 20% more light output power to be transmitted through the surface and exit the LED, as compared to a light output power that is transmitted through a planar, flat, or smooth surface of the p-type layer that has a surface roughness of 1 nm or less.

9. The LED of claim 1, wherein the surface is roughened with features or structures having a side, dimension, width, height and separation so dimensioned as to scatter or diffract the light out of the p-type layer and the LED.

10. The LED of claim 1, wherein the surface is roughened with features or structures having a side, dimension, width, height and separation at least as long as a wavelength of the light in the p-type layer, in order to enhance scattering, diffraction, or transmission of the light out of the p-type layer and the LED.

11. The LED of claim 10, wherein the side, the dimension, the width, the height, and the separation are at least 0.3 μm.

12. The LED of claim 11, wherein the side, the dimension, the height, and the separation are at most 2 μm.

13. The LED of claim 11, wherein the side, the dimension, the height, and the separation are at most 10 μm.

14. The LED of claim 1, wherein the surface is shaped so that light from the active layer impinges on the surface within a critical angle for refraction out of the p-type layer and into an external medium.

15. The LED of claim 1, wherein the surface comprises one or more inclined surfaces so dimensioned that the light impinges on the inclined surfaces within the critical angle, thereby substantially preventing total internal reflection of the light at the inclined surfaces.

16. The LED of claim 15, wherein the inclined surfaces are inclined at the critical angle so that the light impinges on the inclined surfaces within the critical angle and more than 4-6% of the light from the active layer is extracted from the surface.

17. The LED of claim 1, wherein the surface comprises a surface roughness of 25 nm or greater.

18. The LED of claim 1, wherein the roughening is formed on an N-face, Ga-face, nonpolar surface, or semipolar surface of the p-type layer.

19. A method for fabricating a III-nitride based light emitting diode (LED), comprising:
roughening a p-type surface of the III-nitride based light emitting LED, wherein the roughening comprises photoelectrochemically etching the p-type surface and the roughening is suitable to extract light from the LED.

20. A light emitting diode (LED), comprising a roughened surface of a p-type layer, wherein the roughened surface scatters light incident on the roughened surface into an external medium, wherein the light is incident from a light-emitting active layer of the LED.

21. The LED of claim 20, wherein the LED is III-nitride based and the p-type layer is a III-Nitride.

22. A method for extracting light from a light emitting diode, comprising extracting the light from a roughened surface of a p-type III-nitride layer.
